(19) United States
(12) Patent Application Publication
(10) Pub. No.: US 2024/0406624 A1
(43) Pub. Date: Dec. 5, 2024

(54) LOUDSPEAKER EXCURSION PREDICTION SYSTEM

(71) Applicant: ELITE SEMICONDUCTOR MICROELECTRONICS TECHNOLOGY INC., Hsinchu (TW)

(72) Inventors: JUNG-KUEI CHANG, Tainan City (TW); WUN-LONG YU, Hsinchu (TW)

(21) Appl. No.: 18/326,032

(22) Filed: May 31, 2023

(51) Int. Cl. H04R 3/00; H03G 3/20; H04R 29/00

(52) U.S. Cl. CPC H04R 3/007; H03G 3/20; H04R 29/001; H04R 2430/00

(57) ABSTRACT

A loudspeaker excursion prediction system, which is suitable for a loudspeaker protection circuit comprises a low-pass filter circuit, a down-sampling circuit, and an impulse response generation unit. The low-pass filter circuit is configured to generate an audio signal X_{LPF}(t) passing through the low-pass filter circuit according to an audio signal X(t) with a first sampling frequency. A down-sampling circuit, coupled to the low-pass filter circuit, is configured to down-sampling the first sampling frequency of the audio signal X_{LPF}(t) output from the low-pass filter circuit to a second sampling frequency, so as to generate a down-sampled audio signal X_{LPFDN}(t). The impulse response generation unit, coupled to the down-sampling circuit, is configured to generate an excursion prediction value according to a loudspeaker excursion transfer function and the down-sampled audio signal X_{LPFDN}(t).

### BACKGROUND OF THE INVENTION

### 1. Field of the Invention

The present disclosure relates to a loudspeaker excursion estimation circuit, and in particular to a loudspeaker excursion prediction system.

### 2. Description of the Related Art

A loudspeaker substantially consists of a magnet, a coil, and a vibrating diaphragm. An electromagnetic field is produced when a current passes through the coil, such that the coil and the vibrating diaphragm vibrate together and jointly push ambient air to vibrate, and the loudspeaker accordingly generates sounds. The process of energy conversion of a loudspeaker is converting electric energy to magnetic energy, converting magnetic energy to mechanical energy, and then converting mechanical energy to sounds.

The excursion of a loudspeaker refers to the offset by which a vibrating diaphragm, under the action of a driving force, moves from a stationary position to a maximum displacement (to be referred to as an excursion below). The size of the excursion affects performance of a loudspeaker in terms of volume, power, and distortion, and is thus critical for the design and optimization of the loudspeaker. When a loudspeaker goes beyond a maximum excursion limit, temporary or even permanent damage to the loudspeaker may result in a way that the sound generated by the loudspeaker becomes abnormal, distorted, or the loudspeaker becomes incapable of producing sounds at all. Mechanical damage may be caused by collisions between a coil, a vibrating diaphragm, or a voice coil former and a fixing component. In order to prevent a loudspeaker from mechanical damage, the excursion of a vibrating diaphragm needs to be accurately calculated.

In the aspect of excursion prediction for a loudspeaker, one conventional method is to perform excursion prediction on the basis of acoustic modeling and simulation techniques. By means of building a physical model and a drive system of a loudspeaker, vibration and acoustic characteristics of the loudspeaker can be predicted and analyzed. In this case, the loudspeaker is represented by several basic parameters (for example, the parameters include load characteristics, diaphragm elasticity, damping, and so on), and the estimation may also be performed by means of measuring an output current and voltage of the loudspeaker. A unit impulse response filter is established according to the above basic parameters of the loudspeaker to process an output response of the loudspeaker.

The unit impulse response of a loudspeaker refers to a transient response output by the loudspeaker when the loudspeaker is subjected to an impulse signal, and is used to evaluate performance indicators such as frequency response and harmonic distortion of the loudspeaker. By performing Fourier series analysis of the frequency response of a pre-modeled impulse response of the loudspeaker through an input audio signal, the resonant frequency and bandwidth of the loudspeaker can be obtained, further deducing the excursion response predicted under the audio input. An excursion value of the loudspeaker is estimated by using an excursion prediction circuit of an infinite impulse response (IIR) or a finite impulse response (FIR) corresponding to the loudspeaker, and a limit is regulated according to the excursion value for audio signals output to the loudspeaker, so as prevent the problem of the loudspeaker exceeding the maximum excursion limit (Xmax).

### BRIEF SUMMARY OF THE INVENTION

However, in the above excursion prediction circuit, factors including frequency response and system stability often need to be taken into account. In actual applications, the order of impulse response is usually related to the required system precision, and an excursion prediction circuit that adopts a higher-order impulse response can provide higher prediction accuracy. However, calculation and storage amounts are increased. If a filter is adjusted to have a lower order, the excursion prediction accuracy of a loudspeaker deteriorates significantly. Therefore, there is a need for a balance between calculation and storage requirements and the precision in applications of loudspeaker excursion estimation, so as to ensure the optimal order of impulse response.

A 1024-order impulse response generated by a loudspeaker under the same audio input can accurately simulate a predicted excursion response output. When the order of the impulse response is reduced to 128-order, a large error and offset results in the simulated predicted excursion response output, and this occurrence is a prediction error caused by an inadequate resolution. An audio sampling frequency refers to the number of samples of an audio signal within a period of time, and it is usually represented in a unit of number of times of sampling per second, that is, in a unit of Hertz (Hz). Common audio sampling rates (frequency) include 44.1 kHz, 48 kHz, and 96 kHz. The sampling precision of audio signals gets higher as the sampling frequency increases. Refer to FIG. 1A, which illustrates a graph of excursion response distribution of a commercially available full-range loudspeaker. It can be seen that most of the sounds are under a bandwidth of less than 3 kHz. Refer to FIG. 1B showing a graph illustrating excursion response distribution of another commercially available full-range loudspeaker. It can be seen that most of the sounds are also under a bandwidth of less than 3 kHz.

In view of the prior art above, the present disclosure provides a loudspeaker excursion prediction system. With the coordination of a relation among the system structure, audio sampling frequency, and loudspeaker excursion response distribution provided, an effect of high accuracy can still be maintained under the condition of reduced order of impulse response.

To achieve the above and other objects, the present disclosure provides a loudspeaker excursion prediction system, including a low-pass filter circuit, a down-sampling circuit, and an impulse response generation unit. The low-pass filter circuit is configured to generate, according to an audio signal X(t) with a first sampling frequency Fₛ₁, an outputted audio signal X_{LPF}(t) having passed through the low-pass filter circuit. The down-sampling circuit, coupled to the low-pass filter circuit output, is configured to down-sample the first sampling frequency Fₛ₁ of the audio signal X_{LPF}(t) output from the low-pass filter circuit to a second sampling frequency Fₛ₂, so as to generate a down-sampled audio signal X_{LPFDN}(t). The impulse response generation unit, coupled to the down-sampling circuit output, is configured to generate an excursion prediction value Y(t) according to a loudspeaker excursion transfer function H(t) and the down-sampled audio signal X_{LPFDN}(t).

In some embodiments, the first sampling frequency Fₛ₁ is 48 kHz, and the second sampling frequency Fₛ₂ is adjustable.

In some embodiments, the second sampling frequency Fₛ₂ is ⅛ times the first sampling frequency Fₛ₁.

In some embodiments, the second sampling frequency Fₛ₂ is a component of 95% of an excursion response covered within 0.5 times the frequency points.

In some embodiments, the impulse response generation unit is an impulse response filter.

In some embodiments, when the second sampling frequency Fₛ₂ is 6 kHz, the order of the impulse response filter is designed to be 128-order.

In some embodiments, a cutoff frequency of the low-pass filter circuit is less than one-half of the second sampling frequency Fₛ₂.

In some embodiments, a cutoff frequency of the low-pass filter circuit has an attenuation of less than −60 dB of 0.5 times the frequency points of the second sampling frequency Fs2.

In some embodiments, an excursion conversion circuit is further included. The excursion conversion circuit is coupled to the impulse response generation unit, and is configured to generate the loudspeaker excursion transfer function.

In some embodiments, the loudspeaker excursion prediction system further includes: an excursion conversion circuit, coupled to the impulse response generation unit, configured to generate the loudspeaker excursion transfer function; a protection circuit, coupled to the impulse response generation unit, configured to generate a loudspeaker excursion protection value according to the excursion prediction value; a gain controller, coupled to the protection circuit, configured to generate an audio signal with a maximum excursion limit according to a delayed audio signal and the loudspeaker excursion protection value; and a delay circuit, coupled to the gain controller, configured to generate the delayed audio signal according to the audio signal.

Thereby, the loudspeaker excursion prediction system of the present disclosure improves the accuracy of the impulse response generation unit at a low frequency by the down-sampling circuit, and effectively reduces the order of the filter circuit of the impulse response generation unit, further using less memory storage space and a lower DSP operation amount.

### BRIEF DESCRIPTION OF THE DRAWINGS

FIG. 1A is a graph illustrating excursion response distribution of a commercially available full-range loudspeaker of the prior art.

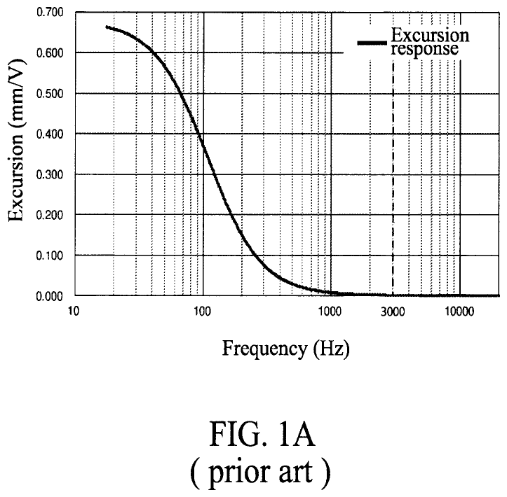

FIG. 1B is a graph illustrating of excursion response distribution of another commercially available full-range loudspeaker of the prior art.

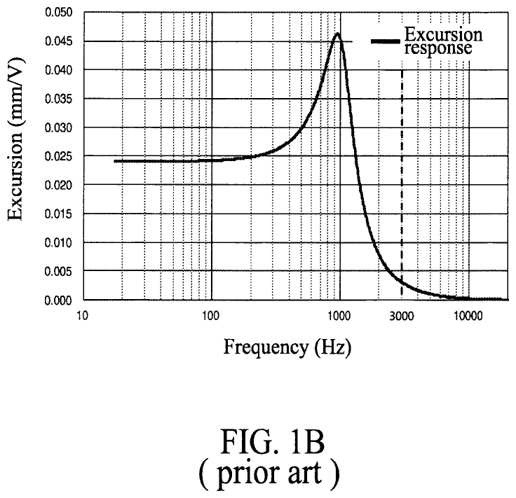

FIG. 2 is a block diagram of a system according to an embodiment of the present disclosure.

FIG. 3 is a graph illustrating a waveform of an input audio signal X(t) according to an embodiment of the present disclosure.

FIG. 4 is a graph illustrating a first sampling frequency Fₛ₁ and a second sampling frequency Fₛ₂ according to an embodiment of the present disclosure.

FIG. 5 is a graph illustrating impulse response when a 128-order finite impulse response filter is used for operation according to an embodiment of the present disclosure.

FIG. 6A is a graph illustrating a simulated waveform of a predicted excursion output according to an embodiment of the present disclosure.

FIG. 6B is a graph illustrating a measured waveform of an actual excursion output according to an embodiment of the present disclosure.

FIG. 7 is a block diagram of a system according to another embodiment of the present disclosure.

FIG. 8 is a block diagram of a system according to yet another embodiment of the present disclosure.

### DETAILED DESCRIPTION OF THE INVENTION

To facilitate understanding of the objectives, characteristics, and effects of the present disclosure, embodiments together with the attached drawings for the detailed description of the present disclosure are provided below.

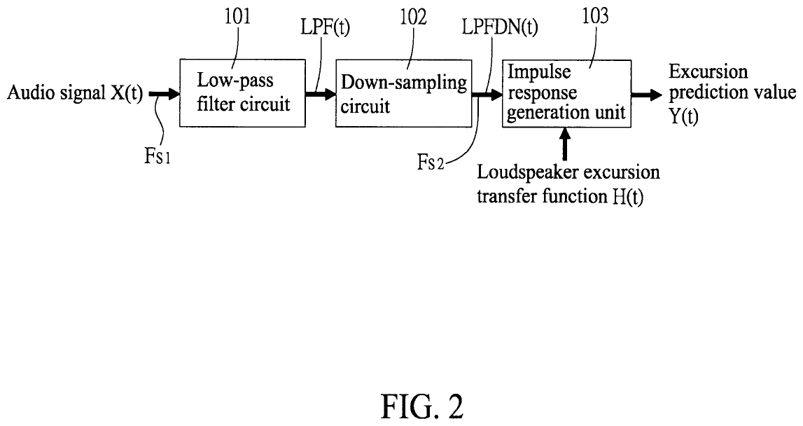

Refer to FIG. 2, which is a block diagram of a system according to an embodiment of the present disclosure. As shown in FIG. 2, a loudspeaker excursion prediction system includes a low-pass filter circuit 101, a down-sampling circuit 102, and an impulse response generation unit 103.

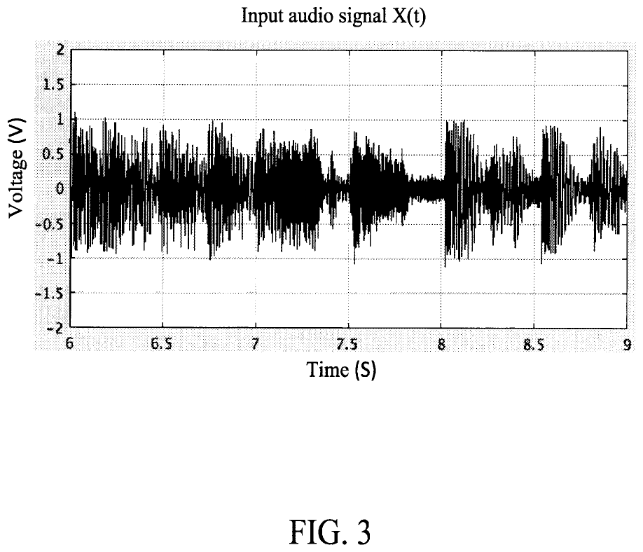

The low-pass filter circuit 101 is configured to generate, according to an audio signal X(t) with a first sampling frequency Fₛ₁, and output an audio signal X_{LPF}(t) having passed through the low-pass filter circuit 101. Refer to FIG. 3, which is a graph of a waveform of the input audio signal X(t) according to an embodiment of the present disclosure, wherein the first sampling frequency Fₛ₁ of the input audio signal X(t) is 48 kHz. It can be seen that the audio signal X(t) in a high frequency band contributes little help or even no help for excursion prediction. Thus, a low frequency band of the audio signal X(t) is extracted by the low-pass filter circuit 101 to generate an audio signal X_{LPF}(t) output having passed through the low-pass filter circuit 101.

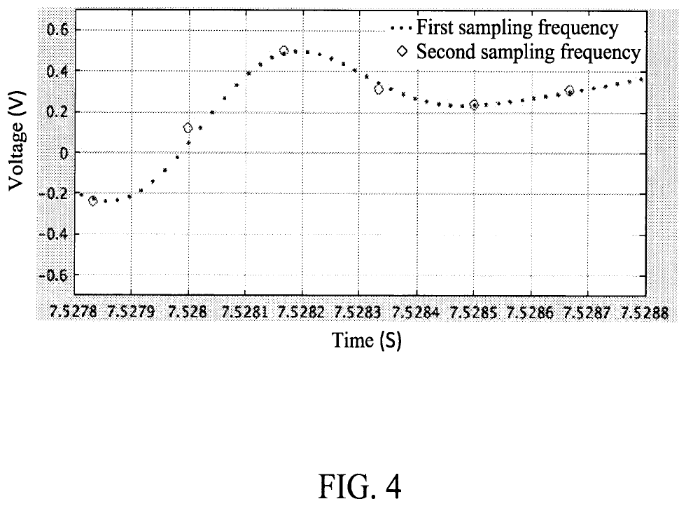

The input of the down-sampling circuit 102 is coupled to the output of the low-pass filter circuit 101. The down-sampling circuit 102 is configured to down-sample the first sampling frequency Fₛ₁ of the audio signal X_{LPF}(t) output from the low-pass filter circuit 101 to a second sampling frequency Fₛ₂, so as to generate a down-sampled audio signal X_{LPFDN}(t). Refer to FIG. 4, which is a graph of the first sampling frequency Fₛ₁ and the second sampling frequency Fₛ₂ according to an embodiment of the present disclosure. It is found that, the second sampling frequency Fₛ₂ of the outputted audio signal X_{LPF}(t) having passed through the low-pass filter circuit 101 and the down-sampling circuit 102 is 6 kHz. Moreover, the down-sampling circuit 102 is beneficial for the design of the order of a filter circuit for the impulse response generation unit 103. More specifically, the down-sampling circuit 102 allows the impulse response generation unit 103 to use a filter of a lower order. In some embodiments, a cutoff frequency of the low-pass filter circuit 101 is less than one-half of the second sampling frequency Fₛ₂. Preferably, one-half of the second sampling frequency Fₛ₂ is less than −60 dB.

In some embodiments, the second sampling frequency Fₛ₂ is adjustable. The second sampling frequency Fₛ₂ is 1/N times the first sampling frequency Fₛ₁, where N is a positive integer. For example, the second sampling frequency Fₛ₂ is ⅛ times the first sampling frequency Fₛ₁. For example, the second sampling frequency Fₛ₂ is 6 kHz when the first sampling frequency Fₛ₁ is 48 kHz, and the second sampling frequency Fₛ₂ is 12 kHz or lower when the first sampling frequency Fₛ₁ is 96 kHz. In some embodiments, the second sampling frequency Fₛ₂ is a component of 95% of the excursion response covered within 0.5 times the frequency points.

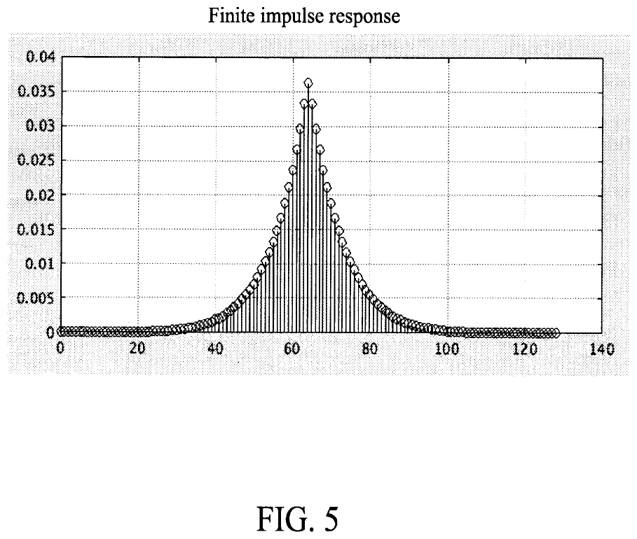

The input of the impulse response generation unit 103 is coupled to the output of the down-sampling circuit 102. The impulse response generation unit 103 is configured to generate an excursion prediction value Y(t) according to a loudspeaker excursion transfer function H(t) and the down-sampled audio signal X_{LPFDN}(t). More specifically, the impulse response generation unit 103 performs a temporal convolution operation on a loudspeaker excursion transfer function H(t) and the down-sampled audio signal X_{LPFDN}(t) to generate the excursion prediction value Y(t) corresponding to a displacement distance. Refer to FIG. 5, which is a graph of impulse response when a 128-order finite impulse response filter is used for operation according to an embodiment of the present disclosure. The impulse response generation unit 103 may be an impulse response filter, for example, a finite impulse response (FIR) filter or an infinite impulse response (IIR) filter. In some embodiments, when the second sampling frequency Fₛ₂ is 6 kHz, the order of the finite impulse response filter is 128-order. When the second sampling frequency Fₛ₂ is 6 kHz, it is suitable for a loudspeaker having a frequency response ranging at 3 kHz.

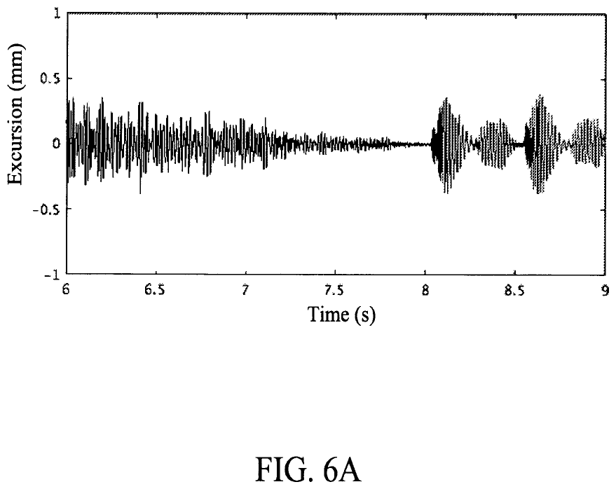

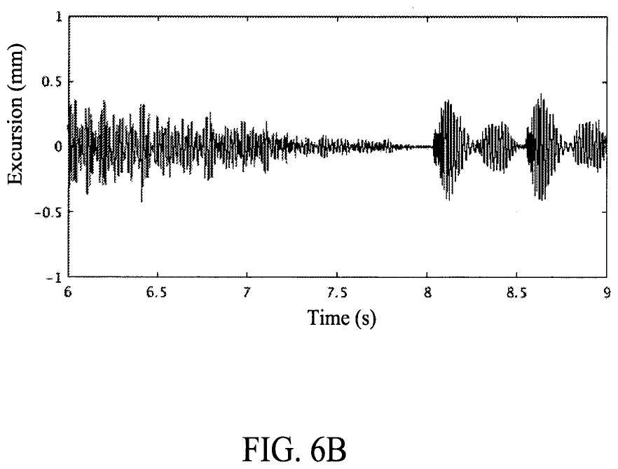

Refer to both FIG. 6A and FIG. 6B, as shown in FIG. 6A and FIG. 6B, the vertical axis represents an excursion value in a unit of millimeters (mm), and the horizontal axis represents time in a unit of seconds(s). FIG. 6A shows a simulated waveform diagram of a predicted excursion output generated by a loudspeaker excursion prediction system. FIG. 6B shows a waveform diagram of an actual excursion output of a loudspeaker measured by a laser rangefinder. It is discovered that the waveforms of the two are very similar, that is to say, the excursion prediction result according to the embodiment of the present disclosure for a loudspeaker has high accuracy.

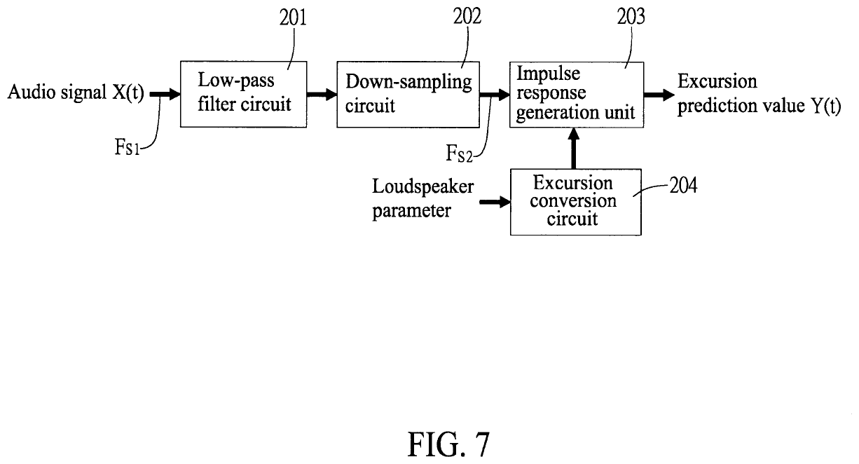

Refer to FIG. 7, which illustrates a block diagram of a system according to an embodiment of the present disclosure. As shown in FIG. 7, a loudspeaker excursion prediction system includes a low-pass filter circuit 201, a down-sampling circuit 202, an impulse response generation unit 203, and an excursion conversion circuit 204. The low-pass filter circuit 201, the down-sampling circuit 202, and the impulse response generation unit 203 disclosed by this embodiment are respectively the same as the low-pass filter circuit 101, the down-sampling circuit 102, and the impulse response generation unit 103 disclosed in FIG. 2, and related details are omitted herein.

The output of the excursion conversion circuit 204 is coupled to an input of the impulse response generation unit 203. The excursion conversion circuit 204 is configured to generate a loudspeaker excursion transfer function H(t) according to a loudspeaker parameter that is input into the excursion conversion circuit 204. Since the loudspeaker parameter belongs to a frequency-domain signal, and can undergo an inverse Laplace operation to generate the loudspeaker excursion transfer function H(t) of a time-domain signal, which then undergoes a related operation with the down-sampled audio signal X_{LPFDN}(t) that is similarly a time-domain signal.

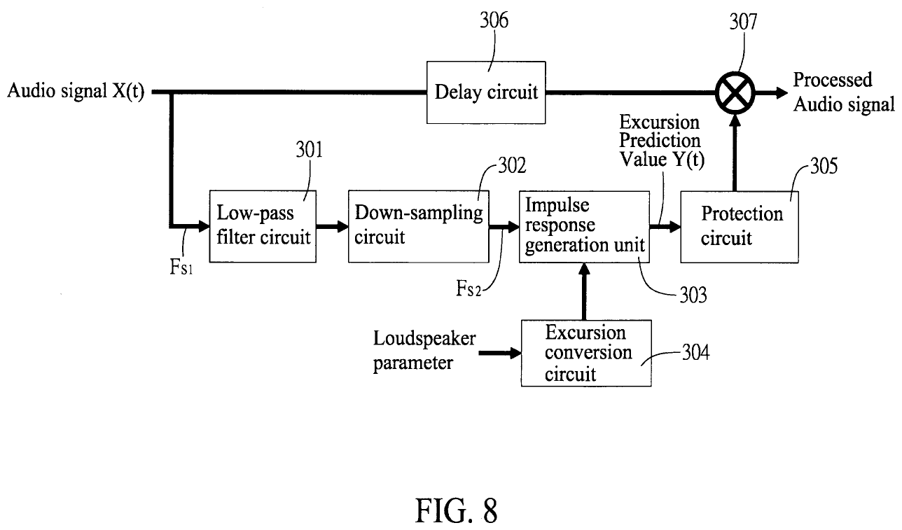

Refer to FIG. 8, which illustrates a block diagram of a system according to an embodiment of the present disclosure. As shown in FIG. 8, a loudspeaker excursion prediction system includes a low-pass filter circuit 301, a down-sampling circuit 302, an impulse response generation unit 303, an excursion conversion circuit 304, a protection circuit 305, a delay circuit 306, and a gain controller 307. The low-pass filter circuit 301, the down-sampling circuit 302, the impulse response generation unit 303, and excursion conversion circuit 304 disclosed by this embodiment are respectively the same as the low-pass filter circuit 201, the down-sampling circuit 202, the impulse response generation unit 203 and the excursion conversion circuit 204 disclosed in FIG. 7, and related details are omitted herein.

The protection circuit 305 is coupled to the impulse response generation unit 303. The input of the protection circuit 305 is configured to generate a loudspeaker excursion protection value to the gain controller 307 according to the excursion prediction value Y(t). The delay circuit 306 is configured to generate a delayed audio signal to the gain controller 307 according to the audio signal X(t). An input of the gain controller 307 is coupled to the output of the protection circuit 305 and another input of the gain controller 307 is coupled to the output of the delay circuit 306. The gain controller 307 is configured to generate the processed audio signal with a maximum excursion limit according to the delayed audio signal and the loudspeaker excursion protection value, so as to prevent the loudspeaker from going beyond the maximum excursion limit (Xmax).

Refer to Table-1 below which illustrates differences of embodiments of the present disclosure compared with the prior art by using experimental results.

TABLE 1

| | Prior art | Present disclosure | Result |
|---|---|---|---|
| Storage | 1024-order | 128-order | The present |
| space | | | disclosure saves |
| | | | ⅛ times the |
| | | | memory space. |
| DSP | 48 kHz*1024 = | 6 kHz* 128 = | The present |
| operation | 48M cycle | 768K cycle | disclosure saves |
| amount | | 1 biquad = 10 cycles | 1/24 times the |
| | | 30*48K = 1440K cycle | DSP operation |
| | 48M cycle | 2208K cycle | amount. |
| Accuracy | >98% | >98% | Both high in |
| | | | accuracy |

As shown in Table-1 above, a 1024-order filter circuit is adopted in an excursion prediction circuit of the prior art, and embodiments of the present disclosure adopt a filter circuit of merely 128 orders. In comparison, the present disclosure saves ⅛ times the memory space in terms of storage space of a memory. With the sampling frequency of 48 kHz and the 1024-order filter circuit adopted in the prior art, an operation needs to be performed on an impulse cycle of 48 Mega in terms of a DSP operation amount in order to obtain a result of an excursion prediction value. In embodiments of the present disclosure, a filter circuit with a sampling frequency of 6 kHz and 128 orders and a low-pass filter circuit are adopted. In terms of estimation, the low-pass filter circuit takes DSP of an impulse cycle of approximate 1440 K (10+1440K) to perform an operation. Thus, in terms of a DSP operation amount, only an impulse cycle of 2208 K is needed in order to obtain a result of the excursion prediction value Y(t). Overall, embodiments of the present disclosure save 1/24 times the DSP operation amount. In other words, given that an excursion prediction value with high accuracy (>98%) can be similarly achieved, the embodiments of the present disclosure take up less memory space and a lower DSP operation amount.

Thereby, the loudspeaker excursion prediction system of the present disclosure improves the accuracy of the impulse response generation unit at a low frequency by the down-sampling circuit, and effectively reduces the order of the filter circuit of the impulse response generation unit, further using less memory storage space and a lower DSP operation amount.

The present invention is described by way of the preferred embodiments above. A person skilled in the art should understand that, these embodiments are merely for illustrating the present invention, and are not to be construed as limitations to the scope of the present invention. It should be noted that all equivalent changes, replacements and substitutions made to the embodiments are encompassed within the scope of the present invention. Therefore, the scope of legal protection for the present invention should be defined by the appended claims.

What is claimed is:

1. A loudspeaker excursion prediction system, comprising:
a low-pass filter circuit, configured to generate an audio signal X_{LPF}(t) having passed through the low-pass filter circuit according to an audio signal X(t) with a first sampling frequency;
a down-sampling circuit, coupled to the low-pass filter circuit, configured to down-sample the first sampling frequency to a second sampling frequency, so as to generate a down-sampled audio signal X_{LPFDN}(t); and
an impulse response generation unit, coupled to the down-sampling circuit, configured to generate an excursion prediction value Y(t) according to a loudspeaker excursion transfer function and the down-sampled audio signal X_{LPFDN}(t).

2. The loudspeaker excursion prediction system according to claim 1, wherein the first sampling frequency is 48 kHz, and the second sampling frequency is adjustable.

3. The loudspeaker excursion prediction system according to claim 1, wherein the second sampling frequency is ⅛ times the first sampling frequency.

4. The loudspeaker excursion prediction system according to claim 1, wherein the second sampling frequency is a component of 95% of an excursion response covered within 0.5 times frequency points.

5. The loudspeaker excursion prediction system according to claim 1, wherein the impulse response generation unit is an impulse response filter.

6. The loudspeaker excursion prediction system according to claim 5, wherein an order of the impulse response filter is designed to be 128-order when the second sampling frequency is 6 kHz.

7. The loudspeaker excursion prediction system according to claim 1, wherein a cutoff frequency of the low-pass filter circuit is less than one-half of the second sampling frequency.

8. The loudspeaker excursion prediction system according to claim 1, wherein one-half of the second sampling frequency is less than −60 dB.

9. The loudspeaker excursion prediction system according to claim 1, further comprising:
an excursion conversion circuit, coupled to the impulse response generation unit, configured to generate the loudspeaker excursion transfer function.

10. The loudspeaker excursion prediction system according to claim 9, further comprising:
a protection circuit, coupled to the impulse response generation unit, configured to generate a loudspeaker excursion protection value according to the excursion prediction value Y(t);
a gain controller, coupled to the protection circuit, configured to generate an audio signal with a maximum excursion limit according to a delayed audio signal and the loudspeaker excursion protection value; and
a delay circuit, coupled to the gain controller, configured to generate the delayed audio signal according to the audio signal X(t).
